(19) United States
(12) Patent Application Publication
(10) Pub. No.: US 2024/0336152 A1
(43) Pub. Date: Oct. 10, 2024

(54) CHARGE PORT WITH FAST PHASE CHANGE MATERIAL (PCM) RESOLIDIFICATION

(71) Applicant: GM GLOBAL TECHNOLOGY OPERATIONS LLC, DETROIT, MI (US)

(72) Inventors: Chih-hung Yen, Bloomfield Hills, MI (US); Satish P. Ketkar, Troy, MI (US); SeungHwan Keum, Northville, MI (US); Peter Paul Andruskiewicz, IV, Ann Arbor, MI (US); Taeyoung Han, Troy, MI (US)

(21) Appl. No.: 18/297,801

(22) Filed: Apr. 10, 2023

(51) Int. Cl. B60L 53/16; F28F 3/02; H01R 13/502; H10N 10/13

(52) U.S. Cl. CPC B60L 53/16; F28F 3/02; H01R 13/502; H10N 10/13; H01R 2201/26

(57) ABSTRACT

Aspects of the disclosure include a charge port having fast phase change material resolidification. An exemplary charge port can include a plug housing and a direct current terminal electrically coupled to the plug housing. A subassembly is coupled to the direct current terminal. The subassembly includes a cartridge filled with a phase change material and an enhancer. The enhancer includes a top portion and a bottom portion. The bottom portion is embedded within the phase change material and the top portion extends beyond the cartridge into ambient. The phase change material removes heat from the direct current terminal when charging. The enhancer removes heat from the phase change material for rapid resolidification.

### INTRODUCTION

The subject disclosure relates to charge ports and electric battery charging technologies, and particularly to a charge port having a fast phase change material (PCM) resolidification for frequent direct current fast charging (DCFC).

High voltage electrical systems are increasingly used to power the onboard functions of both mobile and stationary systems. For example, in motor vehicles, the demand to reduce emissions has led to the development of advanced electric vehicles (EVs). EVs rely upon Rechargeable Energy Storage Systems (RESS), which typically include one or more high voltage battery packs, and an electric drivetrain to deliver power from the battery to the wheels. Battery packs can include any number of interconnected battery modules depending on the power and energy needs of a given application. Each battery module includes a collection of conductively coupled electrochemical cells. The battery pack is configured to provide a Direct Current (DC) output voltage at a level suitable for powering a coupled electrical and/or mechanical load (e.g., an electric motor).

The capacity of a battery pack must be periodically recharged, typically via a charge port. Alternative current (AC) charging is the most common kind of charging and, while somewhat slow, only requires access to a typical AC outlet. An AC charger provides AC power to an on-board charger of a vehicle. The on-board charger converts the AC power to DC power prior to entering the battery. The acceptance rate of an on-board charger is natively limited by various factors, such as, for example, cost, space, and weight. DC fast charging bypasses on-board charger limitations by providing DC power directly to the battery, allowing for faster charge speeds.

### SUMMARY

In one exemplary embodiment a charge port can include a plug housing and a direct current terminal electrically coupled to the plug housing. A subassembly is coupled to the direct current terminal. The subassembly includes a cartridge filled with a phase change material and an enhancer. The enhancer includes a top portion and a bottom portion. The bottom portion is embedded within the phase change material and the top portion extends beyond the cartridge into ambient. The phase change material removes heat from the direct current terminal when charging. The enhancer removes heat from the phase change material during charging and between charging events for more rapid resolidification.

In addition to one or more of the features described herein, in some embodiments, the charge port further includes a thermoelectric device in contact with the enhancer. In some embodiments, a heat sink is positioned on a surface of the thermoelectric device.

In some embodiments, a controller is configured to adjust a thermoelectric device current of the thermoelectric device responsive to a temperature of the phase change material.

In some embodiments, a top portion of the enhancer includes one or more fins and the bottom portion of the enhancer includes one or more plates.

In some embodiments, an interface between the top portion of the enhancer and the bottom portion of the enhancer includes a threaded cap.

In some embodiments, the enhancer includes a fill nipple having a first opening in ambient and a second opening in the cartridge.

In another exemplary embodiment a vehicle includes an electric motor, a battery pack electrically coupled to the electric motor, and a charge port. The charge port can include a plug housing and a direct current terminal electrically coupled to the plug housing. A subassembly is coupled to the direct current terminal. The subassembly includes a cartridge filled with a phase change material and an enhancer. The enhancer includes a top portion and a bottom portion. The bottom portion is embedded within the phase change material and the top portion extends beyond the cartridge into ambient. The phase change material removes heat from the direct current terminal when charging. The enhancer removes heat from the phase change material for rapid resolidification.

In yet another exemplary embodiment a method for rapid phase change material resolidification in a charge port can include providing a plug housing and a direct current terminal electrically coupled to the plug housing. A subassembly is coupled to the direct current terminal. The subassembly includes a cartridge filled with a phase change material and an enhancer. The enhancer includes a top portion and a bottom portion. The bottom portion is embedded within the phase change material and the top portion extends beyond the cartridge into ambient. The phase change material removes heat from the direct current terminal when charging. The enhancer removes heat from the phase change material for rapid resolidification.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 is a vehicle configured in accordance with one or more embodiments;

FIG. 2 is a view of a charge port in accordance with one or more embodiments;

FIG. 3 is a view of a subassembly in accordance with one or more embodiments;

FIG. 4 is a view of an enhancer in accordance with one or more embodiments;

FIG. 5A is a view of an enhancer having a first configuration in accordance with one or more embodiments;

FIG. 5B is a view of an enhancer having a second configuration in accordance with one or more embodiments;

FIG. 5C is a view of an enhancer having a third configuration in accordance with one or more embodiments;

FIG. 6 is a view of an alternative embodiment of the subassembly shown in FIG. 3;

FIG. 7 is a view of an another alternative embodiment of the subassembly shown in FIG. 3;

FIG. 8 is a view of yet another alternative embodiment of the subassembly shown in FIG. 3;

FIG. 9A is a view of a subassembly in accordance with one or more embodiments;

FIG. 9B depicts a block diagram of temperature control logic for a controller in accordance with one or more embodiments;

FIG. 10 is a computer system according to one or more embodiments; and

FIG. 11 is a flowchart in accordance with one or more embodiments.

### DETAILED DESCRIPTION

The following description is merely exemplary in nature and is not intended to limit the present disclosure, its application or uses. It should be understood that throughout the drawings, corresponding reference numerals indicate like or corresponding parts and features.

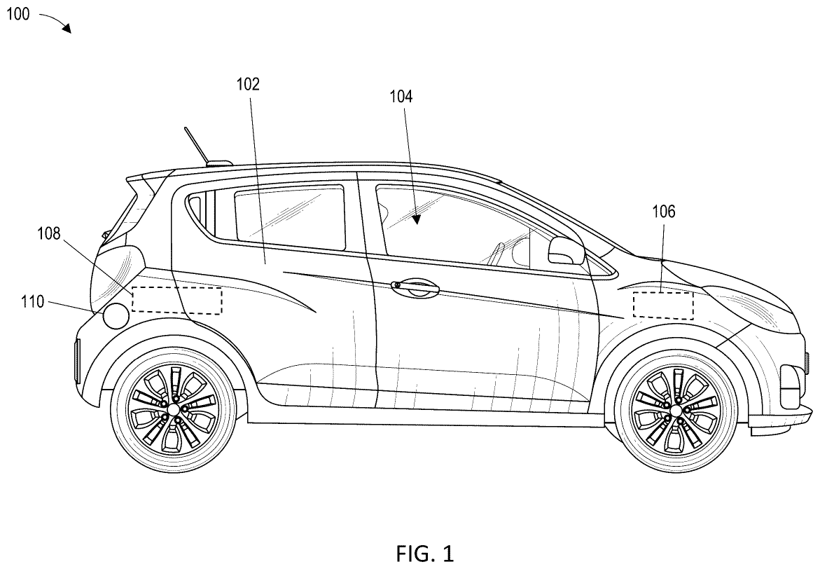

A vehicle, in accordance with an exemplary embodiment, is indicated generally at 100 in FIG. 1. Vehicle 100 is shown in the form of an automobile having a body 102. Body 102 includes a passenger compartment 104 within which are arranged a steering wheel, front seats, and rear passenger seats (not separately indicated). Within the body 102 are arranged a number of components, including, for example, an electric motor 106 (shown by projection under the front hood) and a battery pack 108 (shown by projection near the rear of the vehicle 100). The electric motor 106 and battery pack 108 are shown for ease of illustration and discussion only. It should be understood that the configuration, location, size, arrangement, etc., of the electric motor 106 and/or battery pack 108 is not meant to be particularly limited, and all such configurations (including multi-motor and/or multi-pack configurations) are within the contemplated scope of this disclosure.

As will be detailed herein, the battery pack 108 is recharged via a charge port 110. The charge port 110 is shown for ease of illustration and discussion only. It should be understood that the configuration, location, size, arrangement, etc., of the charge port 110 is not meant to be particularly limited, and all such configurations are within the contemplated scope of this disclosure. Moreover, while the present disclosure is discussed primarily in the context of a charge port 110 configured for recharging a battery pack 108 of the vehicle 100, aspects described herein can be similarly incorporated within any charging system (vehicle, building, or otherwise) having an energy storage system(s) (e.g., one or more battery packs), and all such configurations and applications are within the contemplated scope of this disclosure.

As discussed previously, DC fast charging bypasses the on-board charger limitations associated with AC chargers by providing DC power directly to a battery, allowing for faster charging speeds. The onboard charging port may need to be cooled when recharging to limit the charge port pin temperatures, which increase during Direct Current Fast Charging (DCFC). Without a cooling solution, the pin temperatures can elevate beyond thermal limits, potentially resulting in a charging station shutdown, a charging halt, and/or a slow, thermally degraded charging speed.

One solution is to run a liquid coolant loop to the charging port. Unfortunately, liquid cooling loops are somewhat costly, complex, and inefficient. Cooling loops also increase manufacturing work and complexity and are typically fully active systems that are natively subject to maintenance requirements.

This disclosure introduces a passive cooling solution for charging ports. The passive solution described herein utilizes the latent heat (solid-liquid state transition) of a Phase Change Material (PCM) to temporarily absorb waste heat at the charge port during a DCFC. The charge port includes a continuous two-part structure, referred to herein as an enhancer, to efficiently remove the waste heat stored in the PCM during DCFC. The enhancer includes (1) a heat-conduction-enhancing portion embedded within the PCM for faster and more even melting during heating and cooling operations, and (2) a heat dissipation portion extending beyond the PCM into the ambient to reliably discharge the stored heat between DCFC events. The enhancer efficiently removes the heat stored in the PCM during DCFC—allowing the PCM to be more rapidly resolidified (i.e., transitioned back to its solid state) before the next charging cycle. As a result, charging ports described herein enable faster DCFC charge cycling (i.e., a reduction in downtime between DCFCs) and lower sustained charge port temperatures.

Charge ports constructed with enhancers for fast PCM resolidification in accordance with one or more embodiments offer several technical advantages over other charge port layouts. In short, the charge ports described herein leverage phase change material(s) to absorb the high heat flux spike during charging while much more slowly and gradually dissipating it through the enhancer in the period between charges in a way that can be done passively and/or actively at much lower power and cost than prior charge port designs. In particular, charge port temperatures can be controlled below thermal limits in a passive manner, enabling more frequent DCFC cycling. A typical interval between DCFC is estimated to be less than about 3 hours. Moreover, improved charge port cooling can increase range by approximately 40 percent over a 30 minute charge duration.

Passive cooling solutions described herein can be combined with additional passive and/or active systems (e.g., heat pipes, loop heat pipes, cooling loops, Thermo-Electric Generators (TEGS), fans, etc.) to further decrease the cooling interval, without relying fully on an active solution. Notably, if an integrated active cooling component fails, the charge port can still provide DCFC due to the passive cooling solution, increasing reliability by providing redundancy. In addition, the packaging space in existing charge ports can be modified to include the enhancer, allowing for straightforward retrofitting.

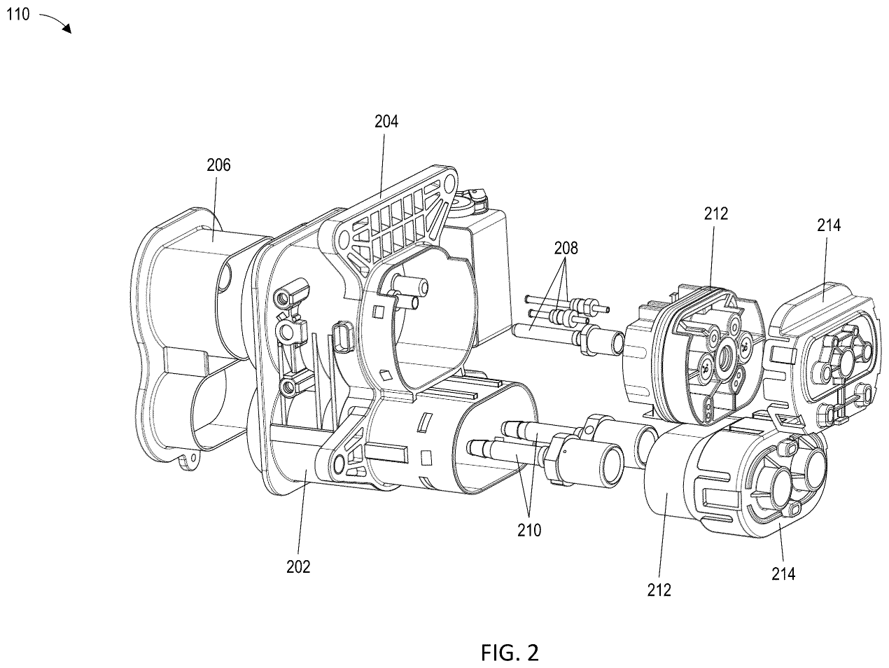

FIG. 2 illustrates a view of the charge port 110 in accordance with one or more embodiments. The charge port 110 can be electrically coupled to a battery pack of an electric vehicle (e.g., the battery pack 108 of vehicle 100), although other charging applications (for vehicles, structures, or otherwise) are within the contemplated scope of this disclosure. The following sections describe the charge port 110 in the context of the vehicle 100 for ease of discussion and illustration. In some embodiments, the charge port 110 includes a variety of structural and/or electrical components. The various structural and electrical components described with respect to FIG. 2 are not meant to be particularly limited, but are illustrative of the components of a charging port.

In some embodiments, the charge port 110 includes a plug housing 202 (also referred to as a front housing) fixed to the body 102 of the vehicle 100 via a mounting flange 204. In some embodiments, the mounting flange 204 is incorporated within (as part of) the plug housing 202. In some embodiments, a front cover 206 protects the plug housing 202 (and other components) from dust and/or water intrusion.

In some embodiments, the plug housing 202 serves as a housing for various electrical components of the charge port 110. The electrical components can include, for example, various AC terminals 208 (also referred to as “pins”) and DC terminals 210 (also referred to as “pins”). In some embodiments, the AC terminals 208 include one or more AC, low voltage, and/or ground pins.

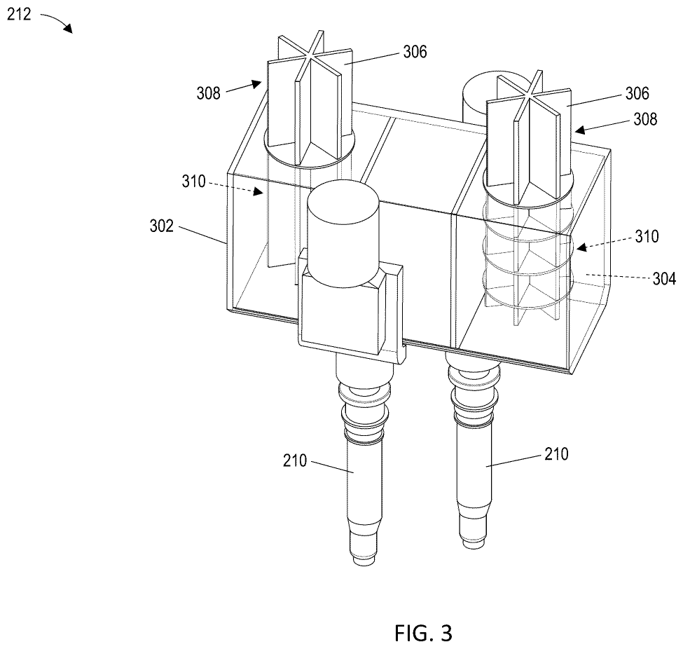

In some embodiments, the DC terminals 210 and/or the AC terminals 208 are housed within a subassembly 212 (also referred to as a rear housing). The subassembly 212 is described in greater detail with respect to FIG. 3. In some embodiments, the subassembly 212 is fit to a rear cover 214. In some embodiments, the rear cover 214 includes various cable seals (e.g., DC/AC/LV/GND cable exit seals, covers, etc.) to further protect the plug housing 202 components from dust and/or water intrusion.

FIG. 3 illustrates a view of the subassembly 212 in accordance with one or more embodiments. In some embodiments, the subassembly 212 includes one or more pins, also referred to as terminals (e.g., the pair of DC terminals 210 in FIG. 2). As described previously, the temperature of the pins increases during charging operations (i.e., when a current is fed through the charge port 110 to the battery pack 108). As shown in FIG. 3, the subassembly 212 is modified to include a PCM cartridge (or housing) 302 configured to remove heat from the pins (e.g., DC terminals 210) during a charging operation.

In some embodiments, the PCM cartridge 302 is fully or partially filled with a phase change material 304. The phase change material 304 can be made from combinations of known phase-change materials with heat-spreading matrices, forming Phase-Change Composite Materials (PCCMs) utilizing heat-spreading matrices made of, for example, expanded graphite, metallic foams, meshes or fins. The specific phase change material selected for a given application is not meant to be particularly limited. While primarily described with respect to phase change materials undergoing a solid-to-liquid phase change, other phase change materials are possible, including those undergoing liquid-to-gas and solid-direct-to-gas. Other phase-change materials can include, for example, organic PCMs (e.g., hydrocarbons such as paraffins, lipids, sugar alcohols, etc.), inorganic PCMs (e.g., salt hydrates), metallic PCMs (e.g. Cerrolow, Field's metal, etc.), and other materials which absorb or release large amounts of latent heat during phase transitions, are within the contemplated scope of the disclosure.

In some embodiments, the phase change material 304 temporarily absorbs waste heat from one or more pins (e.g., the DC terminals 210) during a charging operation (e.g., during DCFC). In some embodiments, the phase change material 304 begins a charging operation in a fully or substantially fully (i.e., greater than 90 percent) solid state. In some embodiments, the phase change material 304 melts (i.e., undergoes a solid-liquid transition) while absorbing heat during the charging operation. In some embodiments, the phase change material 304 ends a charging operation in a fully or substantially fully (i.e., greater than 90 percent) liquid state. It should be understood that the starting and ending solid/liquid state of the phase change material 304 depends on the specifics of a given situation (e.g., how long from last charge, duration of last charge, duration of current charge, etc.).

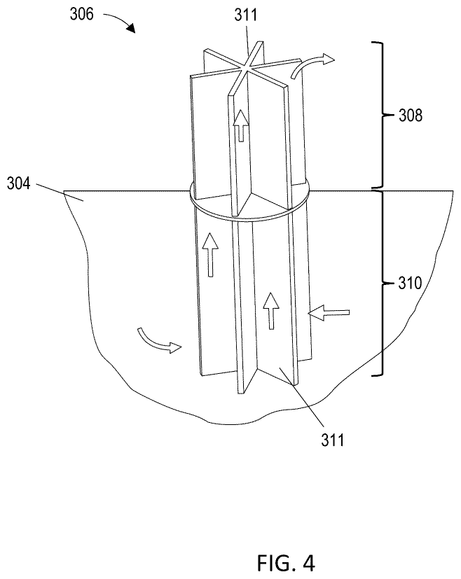

In some embodiments, the PCM cartridge 302 includes an enhancer 306 embedded (submerged) in the phase change material 304. In some embodiments, the enhancer 306 includes a top portion 308 above the PCM cartridge 302 and a bottom portion 310 within the PCM cartridge 302. The enhancer 306 is described in greater detail with respect to FIG. 4. In some embodiments, the PCM cartridge 302 includes two or more enhancers 306. The enhancer 306 is shown in a particular number (here, two) and arrangement (here, on opposite ends of the pins) for ease of illustration and discussion, the number and positioning of the enhancer(s) in the PCM cartridge 302 is not meant to be particularly limited and all such configurations are within the contemplated scope of this disclosure.

In some embodiments, the respective configuration of the enhancer(s) 306 are the same. In some embodiments, the respective configuration of the enhancer(s) 306 are different. In some embodiments, any of the diameter, height, material, number of elements (fins), top portion 308 configuration, and/or bottom portion 310 configuration of an enhancer 306 can be different. For example, the two enhancers 306 shown in FIG. 3 have the same top portion 308 configuration, but a different bottom portion 310 configuration (fins vs. fins and plates).

FIG. 4 illustrates a view of an enhancer 306 in accordance with one or more embodiments. As described previously, the enhancer 306 includes a top portion 308 and a bottom portion 310. In some embodiments, the top portion 308 and the bottom portion 310 are configured the same, or substantially similarly. That is, the top portion 308 and the bottom portion 310 and include a same number and configuration of elements 311 (e.g., fins). In some embodiments, the top portion 308 and the bottom portion 310 are configured differently. That is, the top portion 308 can include a first number and/or arrangement of fins 311 (or other elements, such as plates, screws, etc.) and the bottom portion 310 can include a different number and/or arrangement of fins (or no fins at all, a different element, etc.).

In some embodiments, the top portion 308 is configured as a heat dissipation (convective) portion. In some embodiments, the top portion 308 extends beyond the phase change material 304 into, for example, ambient. In some embodiments, the ambient temperature is at a lower temperature than the top portion 308. In this manner, the top portion 308 can discharge excess heat pulled from the phase change material 304 into ambient. In some embodiments, the top portion 308 is made from a material(s) selected for convection into air, such as, for example, a metal such as aluminum and copper, ceramics, graphite, etc. In some embodiments, the top portion 308 includes a number of fins 311 (here, 6 fins) running vertically (as shown in FIG. 4).

In some embodiments, the bottom portion 310 is configured as a heat-conduction-enhancing portion. In some embodiments, the bottom portion 310 is embedded in the phase change material 304. In some embodiments, the phase change material 304 temperature is at a higher temperature than the bottom portion 310. In this manner, the bottom portion 310 can absorb excess heat from the phase change material 304. In some embodiments, the bottom portion 310 is made from a material(s) selected for conduction (i.e., enhancing thermal conductivity), such as, for example, a metal such as aluminum and copper, ceramics, graphite, etc. In some embodiments, the bottom portion 310 includes a number of fins 311 (here, 6 fins) running vertically (as shown in FIG. 4).

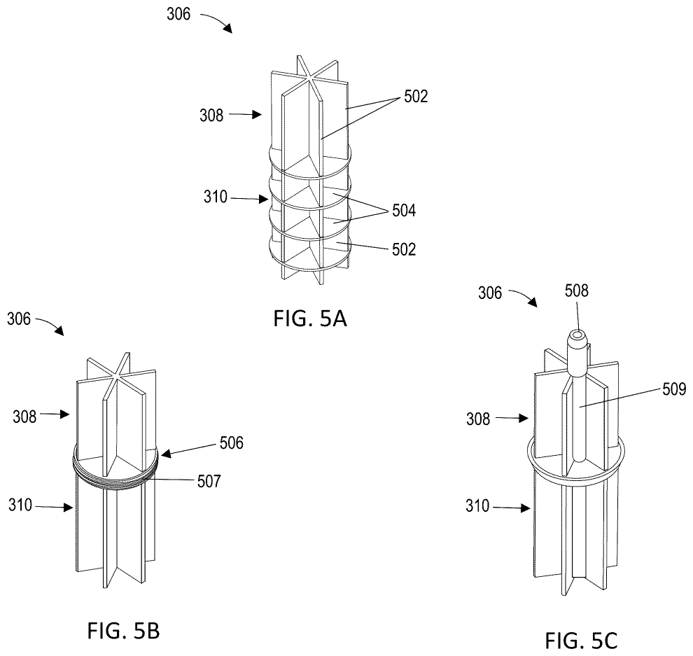

FIG. 5A illustrates a view of an enhancer 306 having a first configuration in accordance with one or more embodiments. As shown, the enhancer 306 includes a top portion 308 and a bottom portion 310. The top portion 308 includes a number of fins 502 (here, 6 fins). The bottom portion 310 includes a combination of fins 502 and plates 504 (here, 6 fins and 4 plates). Configuring the top portion 308 with fins 502 and the bottom portion 310 with fins 502 and plates 504 advantageously allows for optimizations of the top portion 308 and the bottom portion 310. In particular, the top portion 308 can be optimized for convective heat transfer to air while the bottom portion 310 can be optimized for conductive heat transfer.

FIG. 5B illustrates a view of an enhancer 306 having a second configuration in accordance with one or more embodiments. As shown, the enhancer 306 includes a top portion 308 and a bottom portion 310. In some embodiments, the enhancer 306 also includes a cap 506. In some embodiments, the cap 506 is a screw cap and/or threaded cap (also referred to as a sealing member) configured to fix the enhancer 306 to a PCM cartridge (e.g., the PCM cartridge 302 of FIG. 3). In some embodiments, the cap 506 can include first threads 507 and the PCM cartridge 302 can include second, complementary threads such that the top portion 308 and the bottom portion 310 of the enhancer 306 can be screwed or otherwise fixed to the PCM cartridge 302. Advantageously, providing a threaded cap 506 allows for the enhancer 306 to be tightly secured to the PCM cartridge 302, preventing spills of the phase change material 304.

The cap 506 is provided only as an example embodiment for an enhancer 306 that can be fixed (sealed) to the PCM cartridge 302. Other configurations are possible. For example, the enhancer 306 can be sealed to the PCM cartridge via a weld (e.g., laser welding) at the interface between the enhancer 306 and the PCM cartridge 302 (not separately shown). In another example, the enhancer 306 can be sealed to the PCM cartridge via an adhesive (e.g., epoxies, polyurethane, etc.) at the interface between the enhancer 306 and the PCM cartridge 302 (not separately shown).

FIG. 5C illustrates a view of an enhancer 306 having a third configuration in accordance with one or more embodiments. As shown, the enhancer 306 includes a top portion 308 and a bottom portion 310. In some embodiments, the enhancer 306 also includes a fill nipple 508. In some embodiments, the fill nipple 508 is connected to a tube 509 that runs vertically (i.e., between the phase change material 304 and ambient). In this manner, the enhancer 306 can be pre-installed and sealed onto the PCM cartridge 302. The phase change material 304 can then be poured into the fill nipple 508 to fill the PCM cartridge 302 and the fill nipple 508 can be capped and/or otherwise sealed to prevent leakage.

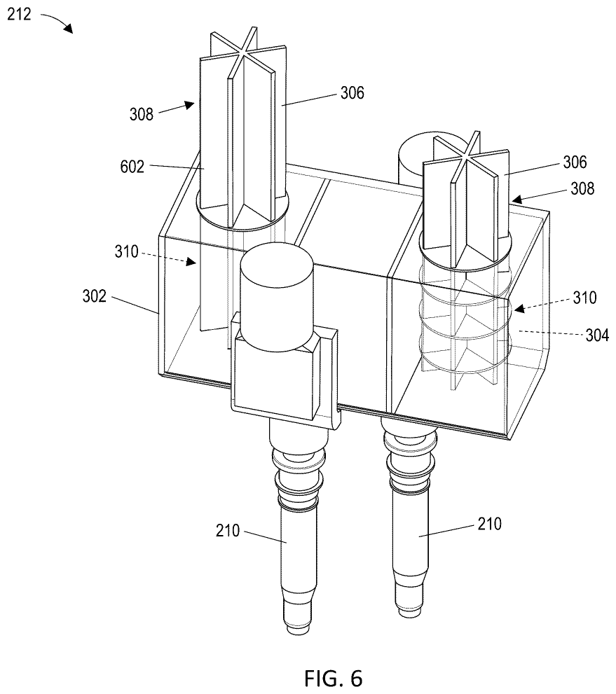

FIG. 6 illustrates a view of an alternative embodiment of the subassembly 212 shown in FIG. 3. The subassembly 212 shown in FIG. 6 can be configured in substantially the same manner as the subassembly 212 shown in FIG. 3, except that the subassembly 212 shown in FIG. 6 can include an extension portion 602. As shown, the top portion 308 of the subassembly 212 includes the extension portion 602, but the bottom portion 310 can be similarly extended depending on the application (not separately shown). For example, such a configuration can be used in retrofits (or other applications) where the PCM cartridge 302 has a fixed dimension but the volume above the PCM cartridge 302 (i.e., in ambient) has clearance for additional enhancer height. Providing an extension portion 602 can improve (increase) waste heat removal from the phase change material 304 and/or waste heat dissipation into ambient.

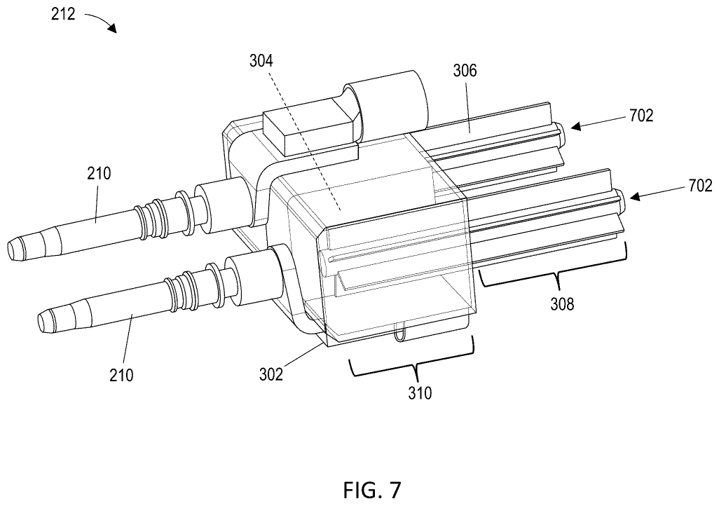

FIG. 7 illustrates a view of an alternative embodiment of the subassembly 212 shown in FIG. 3. The subassembly 212 shown in FIG. 7 can be configured in substantially the same manner as the subassembly 212 shown in FIG. 3, except that the subassembly 212 shown in FIG. 7 can include an enhancer 306 made from and/or integrated with heat pipes 702 to accelerate heat removal from the melted (melting) phase change material 304. In some embodiments, the heat pipes 702 are finned heat pipes.

A heat pipe is a typically closed, thermally conductive pipe (often a metal, such as copper) with a wick on its interior wall (not separately shown). In some embodiments, the heat pipes 702 include a relatively small amount (i.e., less than 10 percent of the internal volume of the heat pipes 702) of working fluid inside the heat pipes 702. In some embodiments, the working fluid includes one or more of water, acetone, methanol, etc.

When heat is applied to one end of a heat pipe (e.g., the portion of the enhancer 306 submerged in the phase change material 304), the liquid near the respective end of the heat pipe will evaporate and the vapor will move to the other end at roughly the speed of sound. When heat is rejected on the other end (e.g., to ambient), the vapor will condense, and the condensate will naturally travel back to the heat input end due to the capillary force provided by the wick. In some embodiments, the value of the equivalent thermal conductivity of the heat pipes 702 is about 1,500 to about 50,000 W/m-K, comparing favorably with copper's thermal conductivity of about 400 W/m-K. In some embodiments, the heat pipes 702 are operated passively, in the absence of pumps and/or an external energy source.

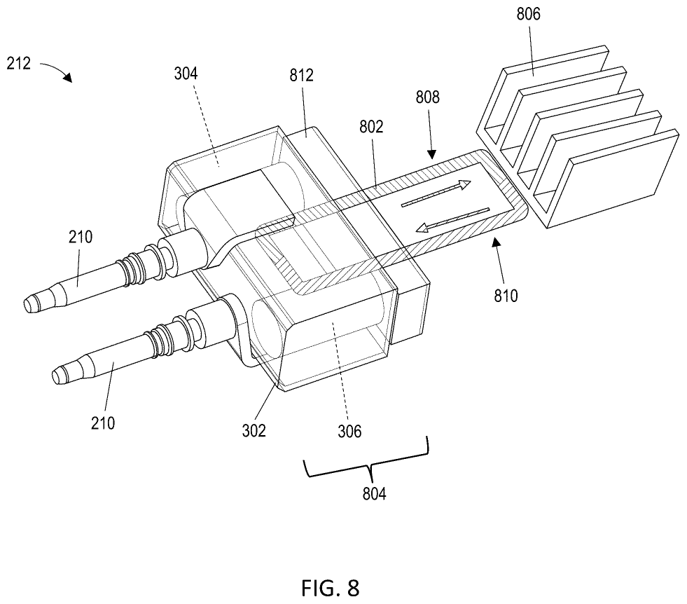

FIG. 8 illustrates a view of an alternative embodiment of the subassembly 212 shown in FIG. 3. The subassembly 212 shown in FIG. 8 can be configured in substantially the same manner as the subassembly 212 shown in FIG. 3, except that the subassembly 212 shown in FIG. 8 can include an enhancer 306 made from and/or integrated with a loop heat pipe 802 to accelerate heat removal from the melted (melting) phase change material 304.

A loop heat pipe operates according to a similar principal as the heat pipe described previously with respect to FIG. 7. However, a loop heat pipe wall is smooth and does not include a wick on the internal pipe wall. A loop heat pipe transfers thermal energy from an evaporator side 804 (referred to as the evaporator) to a condenser side 806 (referred to as the condenser). In some embodiments, the loop heat pipe 802 includes a vapor line 808 that carries a vaporized working fluid (e.g., heated water) from the PCM cartridge 302 to the condenser side 806. In some embodiments, the loop heat pipe 802 includes a liquid line 810 that returns condensed working fluid back to the PCM cartridge 302 from the condenser side 806. In some embodiments, the loop heat pipe 802 includes a manifold 812 to increase heat transfer between the phase change material 804 and the loop heat pipe 802.

In some embodiments, a wick structure (not separately shown) is placed inside the evaporator side 804 at the heat input source (e.g., within the phase change material 304). The evaporator side 804 acts as a capillary force provider in a similar manner as a wick. In some embodiments, the loop heat pipe 802 is operated passively, in the absence of pumps and/or an external energy source.

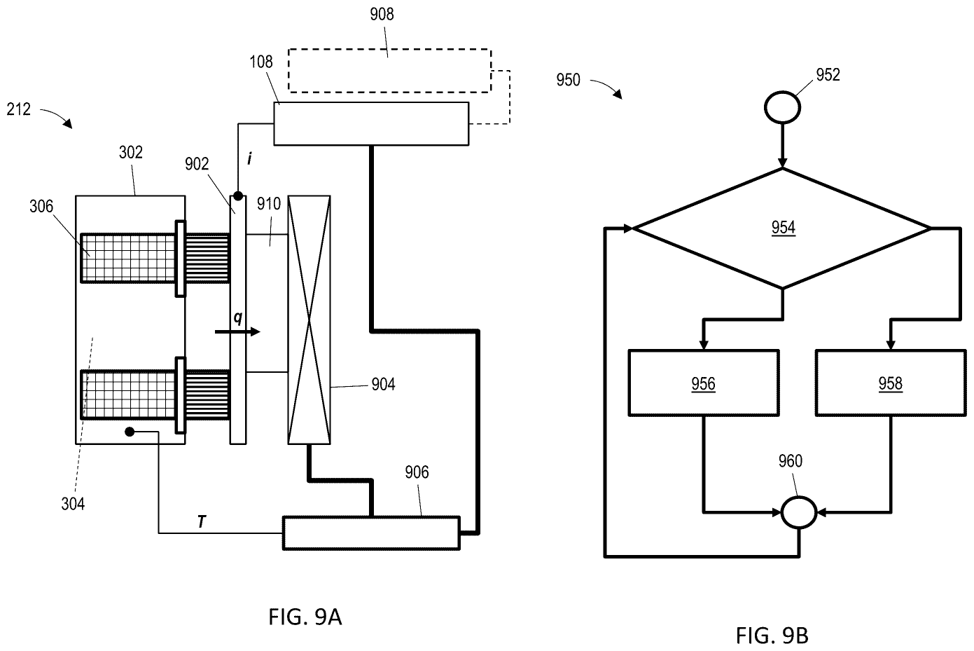

FIG. 9A illustrates a view of an alternative embodiment of the subassembly 212 shown in FIG. 3. The subassembly 212 shown in FIG. 9A can be configured in substantially the same manner as the subassembly 212 shown in FIG. 3, except that the subassembly 212 shown in FIG. 9A can be coupled to a thermoelectric device 902 and/or fan 904.

In some embodiments, the thermoelectric device 902 is a Thermo-Electric Generator (TEG) 902. In some embodiments, the thermoelectric device 902 is positioned on a surface of the enhancer 306 and/or the PCM cartridge 302. Thermoelectric devices leverage the Seebeck effect to harvest waste thermal energy to electricity. For example, in some embodiments, the thermoelectric device 902 is configured to harvest heat from the enhancer 306 (as shown).

The particular configuration of the thermoelectric device 902 in a given application is not meant to be particularly limited, and can include, for example, an alternating array of n- and p-type semiconductors (e.g., bismuth telluride, antimony telluride, lead telluride, bismuth selenide, etc.) having complementary Peltier coefficients soldered or otherwise fixed between a pair of plates (e.g., ceramic plates, metal plates, etc.).

In some embodiments, the thermoelectric device 902 is configured to harvest thermal energy from the enhancer 306 (itself originating from the phase change material 304). In some embodiments, the fan 904 is configured to maintain a temperature difference between both sides of the thermoelectric device 902 to continue the waste energy recovery.

As further shown in FIG. 9A, in some embodiments, a controller (or switch) 906 is coupled to the fan 904 and the thermoelectric device 902. In some embodiments, the controller 906 is coupled to the thermoelectric device 902 via the battery pack 108. In some embodiments, the controller 906 is communicatively coupled to a thermocouple (not separately shown) positioned in, on, or adjacent the phase change material 304. In some embodiments, the thermocouple measures the temperature of the phase change material 304 and sends this signal (“T” in FIG. 9A) to the controller 906. The thermocouple can include a pair of materials (e.g., metals) that are joined together, or coupled, for measuring heat. Thermocouples are widely used in a variety of industries due to their accuracy and large operating range of temperatures. Metals used in thermocouples include iron, nickel, copper, chromium, aluminum, platinum, rhodium, and their alloys.

In some embodiments, such as when the signal “T” is greater than a predetermined limit, the controller 906 is configured to direct the battery pack 108 to send a current “i” to the thermoelectric device 106. In some embodiments, the thermoelectric device 902 transfers heat “q” from the enhancers 306 in response to a difference in current “i” applied at opposite ends of the thermoelectric device 902 by the battery pack 108 due to the Peltier effect. The battery pack 108 can optionally be electrically coupled to one or more additional electricity sources and/or sinks 908 (e.g., a backup power supply, downstream systems, etc.). In some embodiments, the controller 906 is configured with temperature control logic (see, e.g., FIG. 9B).

In some embodiments, the thermoelectric device 902 and/or the fan 904 is coupled to a heat sink 910 to improve heat dissipation to ambient. The heat sink 910 can be made from any suitable material, such as, for example, metals and metal alloys having high or very high thermal conductivities (e.g., aluminum, copper, and alloys thereof), although more exotic materials, such as thermal interface materials, are within the contemplated scope of the disclosure. The heat sink 910 can include, for example, a bulk body and one or more heat dissipating fins, although other configurations are within the contemplated scope of the disclosure.

FIG. 9B depicts a block diagram of temperature control logic 950 for the controller 906 in accordance with one or more embodiments. As shown in FIG. 9B, in some embodiments, the controller 906 is configured to initiate active cooling measures for the enhancer 306 based on the signal “T” and the temperature control logic.

At block 952, a current temperature (“T”) is measured in the phase change material 304. At block 954, the current temperature T is compared to a temperature threshold (“T_{THRESHOLD}”). In some embodiments, the controller 906 determines whether T>T_{THRESHOLD}. The current temperature T can be measured using any suitable device or technique, such as, for example, by a thermocouple (not separately shown) positioned in, on, or adjacent the phase change material 304.

In some embodiments, if the current temperature T is greater than the threshold temperature T_{THRESHOLD} (i.e., block 954 evaluation=YES/TRUE), then the controller 906 turns on (directs power to, etc.) the fan 904 at block 956. In some embodiments, if the current temperature T is less than or equal to the threshold temperature T_{THRESHOLD} (i.e., block 954 evaluation=NO/FALSE), then the controller 906 turns off (or keeps off) the fan 904 at block 958.

At block 960 a new temperature measurement is made and the process repeats at block 954.

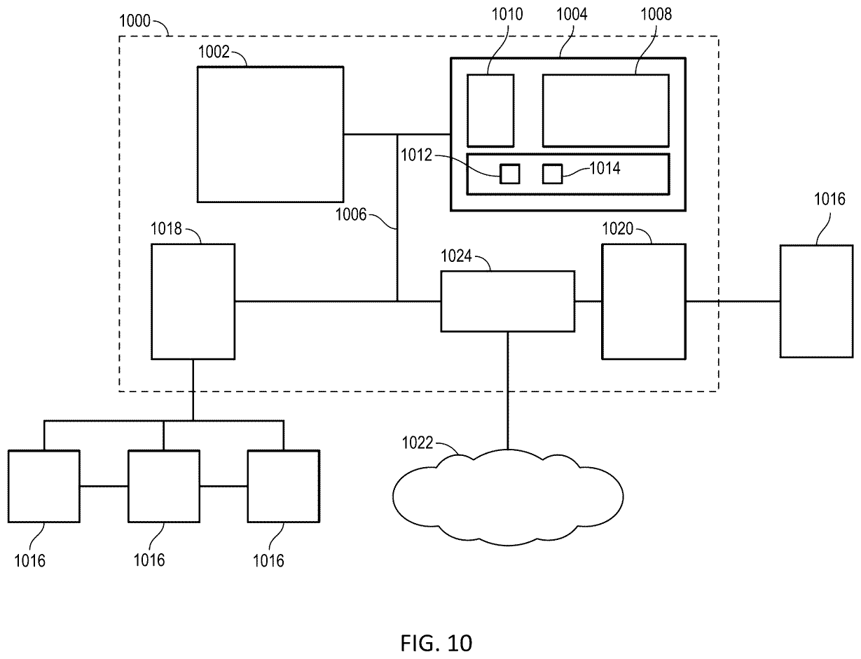

FIG. 10 illustrates aspects of an embodiment of a computer system 1000 that can perform various aspects of embodiments described herein. In some embodiments, the computer system 1000 can be incorporated within or in combination with a battery pack (e.g., the battery pack 108 of FIG. 1) and a charge port (e.g., the charge port 110 of FIG. 1). In some embodiments, the computer system 1000 can be configured to receive a signal (e.g., a temperature signal, etc.) from a phase change material (e.g., the phase change material 304 of FIG. 3).

The computer system 1000 includes at least one processing device 1002, which generally includes one or more processors for performing a variety of functions, such as, for example, controlling power delivery of an electric motor (e.g., the electric motor 106 of FIG. 1) to one or more wheels of a vehicle (e.g., the vehicle 100), controlling charge/discharge rates of one or more batteries (e.g., the battery pack 108 of FIG. 1), and/or monitoring a status of the one or more batteries. In addition, the computer system 1000 can include the logic necessary to estimate and/or to determine a temperature for the phase change material 304 and to take appropriate action based on the data (e.g., initiate active cooling measures, stop charge, slow charge, issue a high temperature warning, etc.).

Components of the computer system 1000 include the processing device 1002 (such as one or more processors or processing units), a system memory 1004, and a bus 1006 that couples various system components including the system memory 1004 to the processing device 1002. The system memory 1004 may include a variety of computer system readable media. Such media can be any available media that is accessible by the processing device 1002, and includes both volatile and non-volatile media, and removable and non-removable media.

For example, the system memory 1004 includes a non-volatile memory 1008 such as a hard drive, and may also include a volatile memory 1010, such as random access memory (RAM) and/or cache memory. The computer system 1000 can further include other removable/non-removable, volatile/non-volatile computer system storage media.

The system memory 1004 can include at least one program product having a set (e.g., at least one) of program modules that are configured to carry out functions of the embodiments described herein. For example, the system memory 1004 stores various program modules that generally carry out the functions and/or methodologies of embodiments described herein. A module or modules 1012, 1014 may be included to perform functions related to monitoring and/or control of the charge port 110 and/or the battery pack 108 as described previously herein. The computer system 1000 is not so limited, as other modules may be included depending on the desired functionality of the vehicle 100. As used herein, the term “module” refers to processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality.

The processing device 1002 can also be configured to communicate with one or more external devices 1016 such as, for example, a keyboard, a pointing device, and/or any devices (e.g., a network card, a modem, vehicle ECUs, etc.) that enable the processing device 1002 to communicate with one or more other computing devices. Communication with various devices can occur via Input/Output (I/O) interfaces 1018 and 1020.

The processing device 1002 may also communicate with one or more networks 1022 such as a local area network (LAN), a general wide area network (WAN), a bus network and/or a public network (e.g., the Internet) via a network adapter 1024. In some embodiments, the network adapter 1024 is or includes an optical network adaptor for communication over an optical network. It should be understood that although not shown, other hardware and/or software components may be used in conjunction with the computer system 1000. Examples include, but are not limited to, microcode, device drivers, redundant processing units, external disk drive arrays, RAID systems, and data archival storage systems, etc.

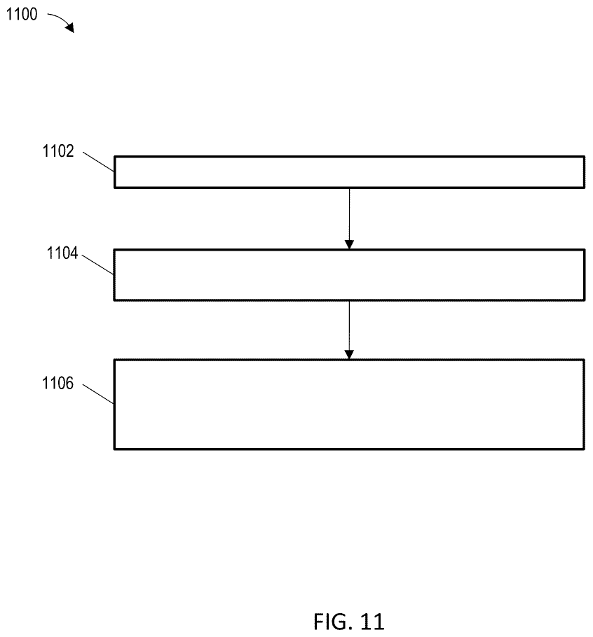

Referring now to FIG. 11, a flowchart 1100 for providing a charge port with a fast PCM resolidification for frequent DCFC is generally shown according to an embodiment. The flowchart 1100 is described in reference to FIGS. 1 to 10 and may include additional steps not depicted in FIG. 11. Although depicted in a particular order, the blocks depicted in FIG. 11 can be rearranged, subdivided, and/or combined.

At block 1102, a plug housing is provided. At block 1104, a direct current terminal is electrically coupled to the plug housing.

At block 1106, a subassembly is coupled to the direct current terminal. In some embodiments, the subassembly includes a cartridge filled with a phase change material and an enhancer. In some embodiments, the enhancer includes a top portion and a bottom portion. In some embodiments, the bottom portion is embedded within the phase change material and the top portion extends beyond the cartridge into ambient.

In some embodiments, the method includes placing a thermoelectric device in contact with the enhancer. In some embodiments, a heat sink is positioned on a surface of the thermoelectric device.

In some embodiments, a controller is configured to adjust a thermoelectric device current of the thermoelectric device responsive to a temperature of the phase change material.

In some embodiments, the top portion of the enhancer includes one or more fins and the bottom portion of the enhancer includes one or more plates. In some embodiments, an interface between the top portion of the enhancer and the bottom portion of the enhancer includes a threaded cap. In some embodiments, the enhancer includes a fill nipple having a first opening in ambient and a second opening in the cartridge.

The terms “a” and “an” do not denote a limitation of quantity, but rather denote the presence of at least one of the referenced item. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

When an element such as a layer, film, region, or substrate is referred to as being “on” another element, it can be directly on the other element or intervening elements may also be present. In contrast, when an element is referred to as being “directly on” another element, there are no intervening elements present.

Unless specified to the contrary herein, all test standards are the most recent standard in effect as of the filing date of this application, or, if priority is claimed, the filing date of the earliest priority application in which the test standard appears.

Unless defined otherwise, technical and scientific terms used herein have the same meaning as is commonly understood by one of skill in the art to which this disclosure belongs.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A charge port comprising:
a plug housing;
a direct current terminal electrically coupled to the plug housing; and
a subassembly coupled to the direct current terminal, the subassembly comprising:
a cartridge filled with a phase change material; and
an enhancer comprising a top portion and a bottom portion, wherein the bottom portion is embedded within the phase change material and the top portion extends beyond the cartridge into ambient.

2. The charge port of claim 1, further comprising a thermoelectric device in contact with the enhancer.

3. The charge port of claim 2, further comprising a heat sink on a surface of the thermoelectric device.

4. The charge port of claim 2, further comprising a controller configured to adjust a thermoelectric device current of the thermoelectric device responsive to a temperature of the phase change material.

5. The charge port of claim 1, wherein the top portion of the enhancer comprises one or more fins and the bottom portion of the enhancer comprises one or more plates.

6. The charge port of claim 1, wherein an interface between the top portion of the enhancer and the bottom portion of the enhancer comprises a threaded cap.

7. The charge port of claim 1, wherein the enhancer comprises a fill nipple having a first opening in ambient and a second opening in the cartridge.

8. A vehicle comprising:
an electric motor configured to drive at least one wheel of the vehicle;
a battery pack electrically coupled to the electric motor; and
a charge port configured to deliver power to at least one of the battery pack and the electric motor, the charge port comprising:
a plug housing;
one or more direct current terminals electrically coupled to the plug housing; and
a subassembly coupled to the one or more direct current terminals, the subassembly comprising:
one or more cartridges filled with a phase change material; and
for each cartridge of the one or more cartridges, an enhancer comprising a top portion and a bottom portion, wherein the bottom portion is embedded within the phase change material and the top portion extends beyond the respective cartridge into ambient.

9. The vehicle of claim 8, further comprising a thermoelectric device in contact with the enhancer.

10. The vehicle of claim 9, further comprising a heat sink on a surface of the thermoelectric device.

11. The vehicle of claim 9, further comprising a controller configured to adjust a thermoelectric device current of the thermoelectric device responsive to a temperature of the phase change material.

12. The vehicle of claim 8, wherein the top portion of the enhancer comprises one or more fins and the bottom portion of the enhancer comprises one or more plates.

13. The vehicle of claim 8, wherein an interface between the top portion of the enhancer and the bottom portion of the enhancer comprises a threaded cap.

14. The vehicle of claim 8, wherein the enhancer comprises a fill nipple having a first opening in ambient and a second opening in the one or more cartridges.

15. A method for phase change material resolidification in a charge port, the method comprising:
providing a plug housing;
providing a direct current terminal electrically coupled to the plug housing; and
providing a subassembly coupled to the direct current terminal, the subassembly comprising:
a cartridge filled with a phase change material; and
an enhancer comprising a top portion and a bottom portion, wherein the bottom portion is embedded within the phase change material and the top portion extends beyond the cartridge into ambient.

16. The method of claim 15, further comprising a thermoelectric device in contact with the enhancer.

17. The method of claim 16, further comprising a heat sink on a surface of the thermoelectric device.

18. The method of claim 16, further comprising a controller configured to adjust a thermoelectric device current of the thermoelectric device responsive to a temperature of the phase change material.

19. The method of claim 15, wherein the top portion of the enhancer comprises one or more fins and the bottom portion of the enhancer comprises one or more plates.

20. The method of claim 15, wherein an interface between the top portion of the enhancer and the bottom portion of the enhancer comprises a threaded cap.
